(19) United States
(12) Patent Application Publication
(10) Pub. No.: US 2024/0071791 A1
(43) Pub. Date: Feb. 29, 2024

(54) SUBSTRATE PROCESSING APPARATUS AND SEMICONDUCTOR DEVICE MANUFACTURING METHOD USING THE SAME

(71) Applicant: Samsung Electronics Co., Ltd., Suwon-si (KR)

(72) Inventors: Tae Soon KANG, Suwon-si (KR); Jin Hee LEE, Suwon-si (KR)

(21) Appl. No.: 18/236,537

(22) Filed: Aug. 22, 2023

(30) Foreign Application Priority Data
Aug. 29, 2022 (KR) 10-2022-0108303

(51) Int. Cl. H01L 21/67

(52) U.S. Cl. CPC H01L 21/67178; H01L 21/6719; H01L 21/67248; H01L 21/67276

(57) ABSTRACT

A method of manufacturing a semiconductor device may comprise loading a first substrate and a second substrate into a substrate processing apparatus, wherein the first substrate is loaded into a first chamber and the second substrate is loaded into a second chamber on the first chamber, and processing the loaded first substrate and the loaded second substrate, wherein the substrate processing apparatus comprises, the first and second chambers, a first pipe through which a first processing solution supplied to the first chamber to process the first substrate is moved, a second pipe through which a second processing solution supplied to the second chamber to process the second substrate is moved, and a temperature adjusting pipe configured to surround at least a part of the first pipe, through which the temperature adjusting solution adjusting a temperature of the first processing solution is moved, wherein a length of the first pipe is shorter than a length of the second pipe.

### CROSS-REFERENCE TO RELATED APPLICATION

This application claims priority from Korean Patent Application No. 10-2022-0108303 filed on Aug. 29, 2022 in the Korean Intellectual Property Office, and all the benefits accruing therefrom under 35 U.S.C. 119, the entire contents of which are herein incorporated by reference.

### BACKGROUND

### 1. Technical Field

The present disclosure relates to a substrate processing apparatus and a semiconductor device manufacturing method using the same.

### 2. Description of the Related Art

As semiconductor devices become more and more highly integrated, the sizes of various patterns constituting each device get more miniaturized. With the miniaturization of the patterns, the pitches of the patterns may not be uniformly formed even when conditions such as temperature, humidity, and time are slightly changed. A semiconductor facility may have a structure where a plurality of chambers are stacked. Furthermore, in the structure, a valve of a pipe may be formed in the lowermost end of the semiconductor facility. A processing solution capable of processing a substrate may be supplied to a lower chamber and an upper chamber, respectively, through the pipe.

As the length of the pipe connected to the lower chamber differs from the length of the pipe connected to the upper chamber, the pattern formed in the lower chamber may not be identical to the pattern formed in the upper chamber. In order to form a uniform miniaturized pattern, strict management of elements such as a temperature of the processing solution for processing the substrate and the processing time thereof should be provided.

### SUMMARY

Aspects of the present disclosure provide a semiconductor device manufacturing method capable of uniformly forming a pattern.

Aspects of the present disclosure also provide a substrate processing apparatus capable of uniformly forming a pattern.

The technical aspects of the present disclosure are not restricted to those set forth herein, and other unmentioned technical aspects will be clearly understood by one of ordinary skill in the art to which the present disclosure pertains by referencing the detailed description of the present disclosure given below.

According to an aspect of the present disclosure, there is provided a semiconductor device manufacturing method, comprising, loading a first substrate and a second substrate into a substrate processing apparatus, wherein the first substrate is loaded into a first chamber and the second substrate is loaded into a second chamber on the first chamber, and processing the loaded first substrate and the loaded second substrate, wherein the substrate processing apparatus comprises the first and second chambers, a first pipe through which a first processing solution is supplied to the first chamber to process the first substrate, a second pipe through which a second processing solution is supplied to the second chamber to process the second substrate, and a temperature adjusting pipe configured to surround at least a part of the first pipe, through which the temperature adjusting solution flows to adjust a temperature of the first processing solution, wherein a length of the first pipe is shorter than a length of the second pipe.

According to another aspect of the present disclosure, there is provided a substrate processing apparatus, comprising, a first chamber where a first substrate is processed, a second chamber disposed on the first chamber, where a second substrate is processed, a first pipe through which a first processing solution is supplied to the first chamber to process the first substrate, a second pipe through which a second processing solution is supplied to the second chamber to process the second substrate, and a temperature adjusting pipe configured to surround at least a part of the first pipe, through which the temperature adjusting solution flows to adjust a temperature of the first processing solution, wherein a length of the first pipe is smaller than a length of the second pipe.

According to another aspect of the present disclosure, there is provided a substrate processing apparatus, comprising, a first chamber processing a first substrate, wherein the first chamber includes a first support unit configured to support the first substrate and rotate the first substrate, a second chamber disposed on the first chamber, and processing a second substrate, wherein the second chamber includes a second support unit configured to support the second substrate and rotate the second substrate, a valve box disposed under the first chamber, a first pipe through which a first processing solution is supplied to the first chamber to process the first substrate, wherein at least a part of the first pipe is disposed in the valve box, a second pipe through which a second processing solution is supplied to the second chamber to process the second substrate, a cooling flow path configured to supply a cooling fluid to cool the first and second support units, and a temperature adjusting pipe connected to the cooling flow path and configured to surround at least a part of the first pipe. The temperature adjusting pipe may have a temperature adjusting solution flow therethrough to adjust the temperature of the first processing solution. The temperature adjusting pipe may include a first portion disposed in a helical shape to surround at least a part of the first pipe, and a length of the first pipe is shorter than a length of the second pipe.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a top plan view explaining the substrate processing apparatus according to some embodiments of the present disclosure;

FIG. 2 is an exemplary perspective view explaining the substrate processing apparatus of FIG. 1;

FIG. 3 is an exemplary cross-sectional view explaining the substrate processing apparatus of FIG. 1;

FIG. 4 is an exemplary diagram explaining the first chamber and the second chamber of FIG. 3;

FIG. 5 is an exemplary diagram explaining the first valve box of FIG. 3;

FIG. 6 is a conceptual diagram explaining a substrate processing apparatus according to some embodiments of the present disclosure;

FIG. 7 is an enlarged view illustrating the first pipe and the first portion of the temperature adjusting pipe of FIG. 6;

FIGS. 8 and 9 are views explaining the substrate processing apparatus according to some embodiments;

FIG. 10 is a graph illustrating the effect of the substrate processing apparatus according to some embodiments; and

FIGS. 11 and 12 are flowcharts explaining a method for operating a substrate processing apparatus according to some embodiments.

### DETAILED DESCRIPTION OF THE EMBODIMENT

It should be appreciated that ordinal numbers such as “first,” “second,” etc. may be used simply as labels to distinguish similar elements and/or components from one another. Unless context indicates otherwise, these elements and/or components are of course not limited by such labeling. It should also be appreciated that a term that is referenced with a particular ordinal number (e.g., “first” in a particular claim) may be referenced elsewhere with a different ordinal number (e.g., “second” in the specification or another claim).

Hereinafter, embodiments of the present disclosure will be described with reference to the attached drawings. The same/or similar numbers (or reference labels) may be used to reference the same/similar elements throughout.

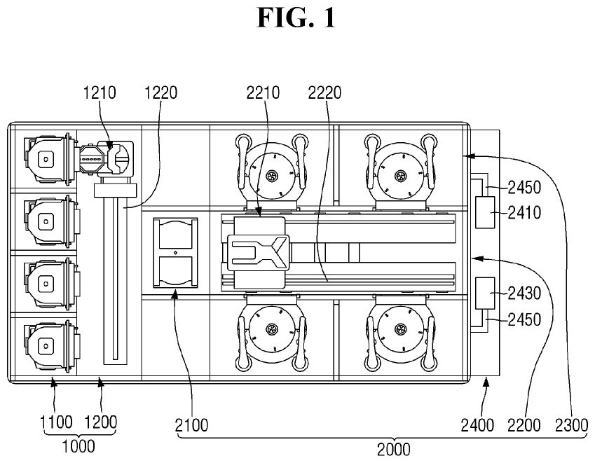

Hereinafter, a substrate processing apparatus according to some embodiments will be described with reference to FIG. 1. FIG. 1 is a top down view illustrating a substrate processing apparatus according to some embodiments of the present disclosure.

Referring to FIG. 1, the substrate processing apparatus according to some embodiments may include an index module 1000 and a process module 2000.

The index module 1000 receives substrates from the outside and provides the substrates to the process module 2000. Substrates referenced in the present application may be a base substrate (e.g., a silicon bulk substrate, a silicon-on-insulator substrate, etc.) and/or may be wafer being processed (e.g., an intermediate product including a base substrate and one or more layers formed thereon) during a semiconductor manufacturing process to form an integrated circuit semiconductor device (e.g., a semiconductor chip). The process module 2000 may perform at least one of a cleaning process, a deposition process, and an etching process. The index module 1000 may be an equipment front end module (EFEM). The index module 1000 may include a load port 1100 and a transfer frame 1200.

The load port 1100 may accommodate the substrates. The substrates may be placed in a container within the load port 1100. A front opening unified pod (FOUP) may be used as the container. The container may be delivered from the outside to the load port 1100 by an overhead transfer (OHT). The container may be delivered from the load port 1100 to the outside by the OHT. The transfer frame 1200 may move the substrates between the container placed in the load port 1100 and the process module 2000.

The process module 2000 may be a module that performs a process. The process module 2000 may include a buffer chamber 2100, a transfer chamber 2200, and several process chambers 2300, and a valve box 2400. In some embodiments, the process chambers 2300 may be formed in stacks (e.g., in towers), but the present invention is not limited thereto. In this embodiment, the process chambers 2300 will be described to be stacked on each other in this specification, but other arrangements also may be implemented.

The buffer chamber 2100 provides a space where a substrate moving between the index module 1000 and the process module 2000 temporarily stays. The buffer chamber 2100 may include a buffer slot on which the substrate is placed. A transfer robot 2210 of the transfer chamber 2200 may withdraw the substrate placed in the buffer slot and move the substrate to the process chamber 2300. The buffer chamber 2100 may include a plurality of buffer slots.

The transfer chamber 2200 moves the substrates between the buffer chamber 2100 in the vicinity thereof and a process chamber 2300. The transfer chamber 2200 may include the transfer robot 2210 and the transfer rail 2220. The transfer robot 2210 may move on the transfer rail 2220 and move the substrate.

Each process chamber 2300 may be a substrate processing apparatus. For instance, each process chamber 2300 may perform at least one of a cleaning process, a deposition process, and an etching process. For example, in a process chamber 2300, silicon germanium (SiGe) may be deposited on the substrate, but the present invention is not limited thereto.

One group of the process chambers 2300 may be disposed on one side of the transfer chamber 2200. A second group of the process chambers 2300 may be disposed on the other side of the transfer chamber 2200. In other words, pairs of process chambers 2300 may be disposed to face each other on opposite sides of the transfer chamber 2200.

The plurality of process chambers 2300 may be provided in the process module 2000. Groups of process chambers 2300 may be arranged in a corresponding row on a side of the transfer chamber 2200. However, the technical idea of the present invention is not limited thereto.

The arrangement of the process chambers 2300 is not limited to the aforementioned example, and may vary in consideration of a footprint of the apparatus or process efficiency.

The valve box 2400 may be disposed on one side of the process chamber 2300. The valve box may be a housing (e.g., metal box) and have a first valve 2410, a second valve 2430, and a pipe 2450 disposed in the valve box 2400. The first valve 2410 may be a valve regulating the supply of a processing solution to the process chamber 2300. The second valve 2430 may be a valve regulating the recovery of the processing solution from the process chamber 2300. The processing solution may flow through the pipe 2450.

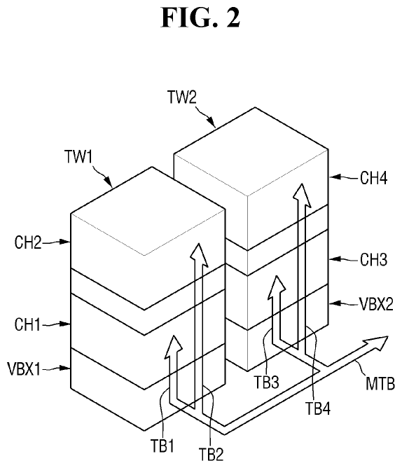

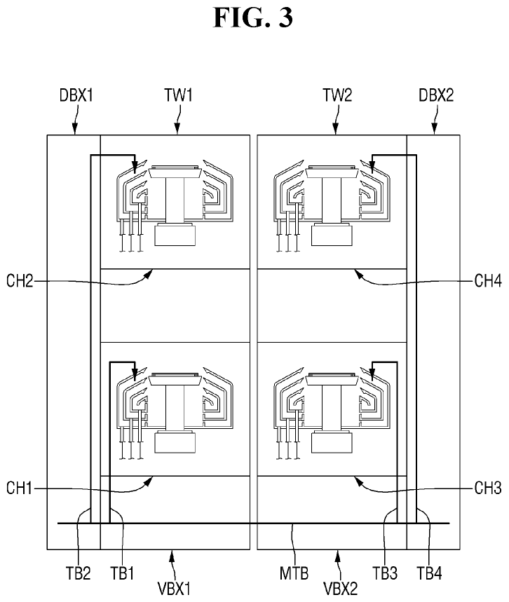

Hereinafter, the substrate processing apparatus according to some embodiments will be described in detail with reference to FIGS. 2 to 9. FIG. 2 is an exemplary perspective view explaining the substrate processing apparatus of FIG. 1. FIG. 3 is an exemplary cross-sectional view explaining the substrate processing apparatus of FIG. 1.

First, referring to FIGS. 2 and 3, a first tower TW1 and a second tower TW2 are provided. Each of the first tower TW1 and the second tower TW2 may comprise a several process chambers 2300 of FIG. 1 (e.g., “CH1,” “CH2,” “CH3” and “CH4”). The first tower TW1 and the second tower TW2 may be arranged side by side in the horizontal direction. Alternatively—unlike the drawings,—the first tower TW1 and the second tower TW2 may be stacked in the vertical direction.

The first tower TW1 may include a first valve box VBX1, a first chamber CH1, a second chamber CH2, and a first distribution box DBX1. Additional chambers CH may be stacked on the first and second chambers CH1, CH2, but only two will be discussed for ease of discussion.

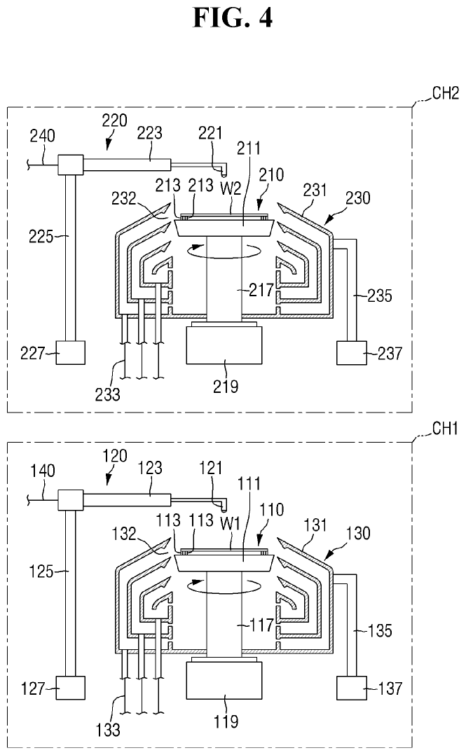

The first chamber CH1 and the second chamber CH2 may be vertically stacked on each other. The second chamber CH2 may be disposed on the first chamber CH1. The substrate may be processed in the first chamber CH1 and the second chamber CH2. A detailed description of the first chamber CH1 and the second chamber CH2 will be described below with reference to FIG. 4.

In the present specification, the term “substrate” may refer to the base substrate itself (e.g., a bulk silicon substrate, SOI, etc.) or a stacked structure (e.g., wafer) including the bulk substrate and one or more layers (e.g., films) formed on a surface thereof. In addition, “the surface of the substrate” may mean an exposed surface of the base substrate itself, or an exposed surface of a layer or film formed on the substrate. For example, the substrate may be a wafer (which may be in the form of a base substrate or an intermediate product including the base substrate as described herein). Layers formed on the substrate may be insulating layers and/or a conductive layers formed by using various methods, such as a deposition process, a coating process, or a plating process. For instance, material layers formed on the wafer may be an insulating layer may be an oxide layer, a nitride layer, or an oxynitride layer, and a conductive layer may be a metal layer or a polycrystalline silicon (poly-Si) layer. Note that a layer may be a single homogenous layer or formed of several distinct layers (e.g., of different materials). In addition, layers formed on the wafer may be patterned.

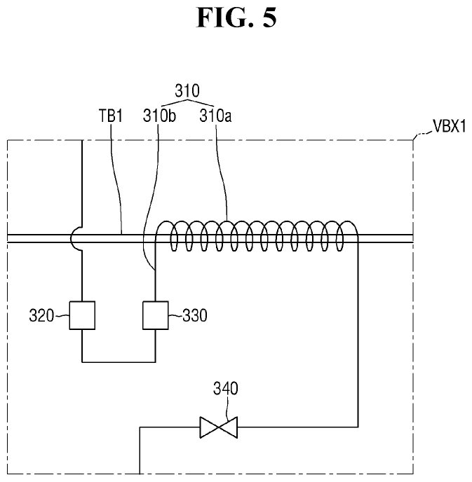

The first valve box VBX1 may be disposed under the first chamber CH1. The first valve box VBX1 may be disposed in the lowermost end (the bottom) of the first tower TW1, but the present invention is not limited thereto. A detailed description of the first valve box VBX1 will be described below with reference to FIG. 5.

The first distribution box DBX1 (e.g., a housing) may be disposed on one side of the first chamber CH1 and the second chamber CH2. A main pipe MTB may be disposed and extend horizontally in the first distribution box DBX1. In some embodiments, a first pipe TB1 and/or a second pipe TB2 may be disposed in the first distribution box DBX1 and extend vertically from the main pipe MTB.

In some embodiments, one end of the first pipe TB1 is connected to the main pipe MTB. The other end of the first pipe TB1 is connected to the first chamber CH1. A first processing solution may be supplied to the first chamber CH1 through the first pipe TB1. A first substrate W1 of FIG. 4 in the first chamber CH1 may be processed using the first processing solution. For instance, when the first processing solution is a cleaning solution, the first substrate may be cleaned using the first processing solution.

In some embodiments, one end of the second pipe TB2 is connected to the main pipe MTB. The other end of the second pipe TB2 is connected to the second chamber CH2. A second processing solution may be supplied to the second chamber CH2 through the second pipe TB2. A second substrate W2 of FIG. 4 in the second chamber CH2 may be processed using the second processing solution. For instance, when the second processing solution is a cleaning solution, the second substrate may be cleaned using the second processing solution.

As illustrated, the second chamber CH2 may be disposed on top of the first chamber CH1. The distance of the second chamber CH2 from the main pipe MTB is thus greater than the distance of the first chamber CH1 from the main pipe MTB. Accordingly, the length of the second pipe TB2 connected to the second chamber CH2 may be longer than the length of the first pipe TB1 connected to the first chamber CH1. The length of each of the first and second pipes TB1 and TB2 may correspond to the respective length of the corresponding fluid path from the main pipe MTB to the corresponding chamber (CH1 or CH2). Thus, the length of the fluid path of the first processing solution (extending from the main pipe to the first processing chamber) is shorter than the length of the fluid path of the second processing solution (extending from the main pipe to the second processing chamber).

For example, when the first and second pipes TB1, TB2 extend vertically from the horizontally extending main pipe MTB, the lengths of the first and second pipes TB1, TB2 substantially correspond to the respective vertical distances from the main pipe MTB to the input port (not shown) of the first and second chambers CH1, CH2 receiving the processing fluid (i.e., to which the first and second inflow lines 140, 240 are connected).

It will be appreciated that when the chambers are identical, the tower formation of stacked chambers CH1, CH2 results in the vertical distance from the main pipe MTB to the input port of the second chamber CH2 to typically be at least twice as long as the vertical distance from the main pipe MTB to the input port of the second chamber CH2. However, if the main pipe MTB is spaced far enough away from the bottom of the first chamber CH1, this MTB to CH2 vertical distance may be slightly less than two times the MTB to CH1 vertical distance. Thus, the length of the second pipe TB2 (and the length of the flow path of the second processing fluid) from the main pipe MTB to the second chamber CH2 may be greater than twice that of or greater than about twice that of (e.g., greater than 1.8 times) the length of the first pipe TB1 (and the length of the flow path of the first processing fluid) from the main pipe MTB to the first chamber CH1.

In some embodiments, the second tower TW2 may include a second valve box VBX2, a third chamber CH3, a fourth chamber CH4, and a second distribution box DBX2.

The third chamber CH3 and the fourth chamber CH4 may be vertically stacked on each other. The fourth chamber CH4 may be disposed on the third chamber CH3. The second valve box VBX2 may be disposed under the third chamber CH3. The second valve box VBX2 may be disposed in the lowermost end (the bottom) of the second tower TW2, but the present invention is not limited thereto.

The second distribution box DBX2 may be disposed on one side of the third chamber CH3 and the fourth chamber CH4. The main pipe MTB may be disposed and extend horizontally in the second distribution box DBX2. In some embodiments, a third pipe TB3 and/or a fourth pipe TB4 may be disposed in the second distribution box DBX2 and extend vertically from the main pipe MTB.

The second tower TW2 may be identical to that of the first tower TW1, and thus, further detailed description thereof will be omitted.

FIG. 4 is an exemplary diagram explaining the first chamber CH1 and the second chamber CH2 of FIG. 3.

Referring to FIG. 4, a first support unit 110, a first nozzle structure 120, and a first recovery unit 130 may be disposed in the first chamber CH1.

The first support unit 110 may support a first substrate W1. The first support unit 110 may rotate the supported first substrate W1. The first support unit 110 may include a first support plate 111, a first support pin 113, a first chuck pin 115, a first rotation shaft 117, and a first rotation driver 119.

The first support plate 111 has an upper surface with a shape identical or similar to the shape of the first substrate W1. The first support pin 113 and the first chuck pin 115 are formed on an upper surface of the first support plate 111. The first support pin 113 supports a bottom surface of the first substrate W1. The first chuck pin 115 may fix the supported first substrate W1.

The first rotation shaft 117 is connected to a lower part of the first support plate 111. The first rotation shaft 117 receives a rotational force from the first rotation driver 119 and rotates the first support plate 111. Accordingly, the first substrate W1 supported by the first support plate 111 may be rotated. The first chuck pin 115 prevents the first substrate W1 from deviating from a normal position.

The first nozzle structure 120 may supply the first processing solution to the first substrate W1. The first processing solution may be, for example, a developer and/or a rinsing solution. The first nozzle structure 120 may include a first arm 123 and a first nozzle 121. The first nozzle structure 120 may include a first nozzle shaft 125 and a first nozzle shaft driver 127.

The first nozzle 121 sprays the first processing solution onto the first substrate W1. The first nozzle 121 may be connected to the first arm 123 and disposed to face the surface of the first substrate W1. The first arm 123 is coupled to the first nozzle shaft 125. The first nozzle shaft 125 is provided to elevate or rotate. The first nozzle shaft driver 127 may elevate or rotate the first nozzle shaft 125 to align the position of the first nozzle 121.

The first recovery unit 130 recovers the first processing solution supplied to the first substrate W1. When the first processing solution is supplied to the first substrate W1 by the first nozzle structure 120, the first support unit 110 may rotate the first substrate W1 so as to uniformly supply the first processing solution to the entire area of the first substrate W1. When the first substrate W1 rotates, the first processing solution is scattered from the first substrate W1. The scattered first processing solution may be recovered by the first recovery unit 130.

The first recovery unit 130 includes a first recovery container 131, a first recovery port 132, first recovery lines 133, a first elevating bar 135, and a first elevating driver 137. The first recovery container 131 is provided in an annular ring shape surrounding the first support plate 111. A plurality of first recovery containers 131 may be provided. As the first recovery container 131 is further away from the first support plate 111, its height increases. A first recovery port 132 into which the first processing solution scattered from the first substrate W1 is introduced is formed in a space between the first recovery containers 131. The first recovery lines 133 are formed in a lower portion of the first recovery container 131.

A first elevating bar 135 is connected to the lower surface of the first recovery container 131. The first elevation bar 135 receives power from the first elevation driver 137 and moves the first recovery container 131 up and down. The first elevating driver 137 may align the position of the first recovery port 132 into which the scattered first processing solution is introduced by elevating the first recovery container 131 through the first elevating bar 135.

A second support unit 210, a second nozzle structure 220, and a second recovery unit 230 may be disposed in the second chamber CH2.

The second support unit 210 may support the second substrate W2. The second support unit 210 may rotate the supported second substrate W2. The second support unit 210 may include a second support plate 211, a second support pin 213, a second chuck pin 215, a second rotation shaft 217, and a second rotation driver 219.

The second support plate 211 has an upper surface with a shape that is identical or similar to the shape of a second substrate W2. The second support pin 213 and the second chuck pin 215 are formed on an upper surface of the second support plate 211. The second support pin 213 supports a bottom surface of the second substrate W2. The second chuck pin 215 may fix the supported second substrate W2.

The second rotation shaft 217 is connected to a lower portion of the second support plate 211. The second rotation shaft 217 receives a rotational force from the second rotation driver 219 and rotates the second support plate 211. Accordingly, the second substrate W2 supported by the second support plate 211 may be rotated. The second chuck pin 215 prevents the second substrate W2 from deviating from the normal position.

The second nozzle structure 220 may supply the second processing solution to the second substrate W2. The second processing solution may be, for example, a developer and/or a rinsing solution. The second nozzle structure 220 may include a second arm 223 and a second nozzle 221. The second nozzle structure 220 may include a second nozzle shaft 225 and a second nozzle shaft driver 227.

The second nozzle 221 sprays the second processing solution onto the second substrate W2. The second nozzle 221 may be connected to the second arm 223 and disposed to face the surface of the second substrate W2. The second arm 223 is coupled to the second nozzle shaft 225. The second nozzle shaft 225 is provided to elevate or rotate. The second nozzle shaft driver 227 may elevate or rotate the second nozzle shaft 225 to align the position of the second nozzle 221.

The second recovery unit 230 recovers the second processing solution supplied to the second substrate W2. When the second processing solution is supplied to the second substrate W2 by the second nozzle structure 220, the second support unit 210 may rotate the second substrate W2 so as to uniformly supply the second processing solution to the entire area of the second substrate W2. When the second substrate W2 rotates, the second processing solution is scattered from the second substrate W2. The scattered second processing solution may be recovered by the second recovery unit 230.

The second recovery unit 230 includes a second recovery container 231, a second recovery port 232, second recovery lines 233, a second elevating bar 235, and a second elevating driver 237. The second recovery container 231 is provided in an annular ring shape surrounding the second support plate 211. A plurality of second recovery containers 231 may be provided. As the first recovery container 231 is further away from the second support plate 211, its height increases. A second recovery port 232 into which the second processing solution scattered from the second substrate W2 is introduced is formed in a space between the second recovery containers 231. The second recovery lines 233 are formed in a lower portion of the second recovery container 231.

The second elevating bar 235 is connected to the lower surface of the second recovery container 231. The second elevating bar 235 receives power from the second elevating driver 237 and moves the second recovery container 231 up and down. The second elevating driver 237 may adjust the position of the second recovery port 232 into which the scattered second processing solution is introduced by elevating the second recovery container 231 through the second elevating bar 235.

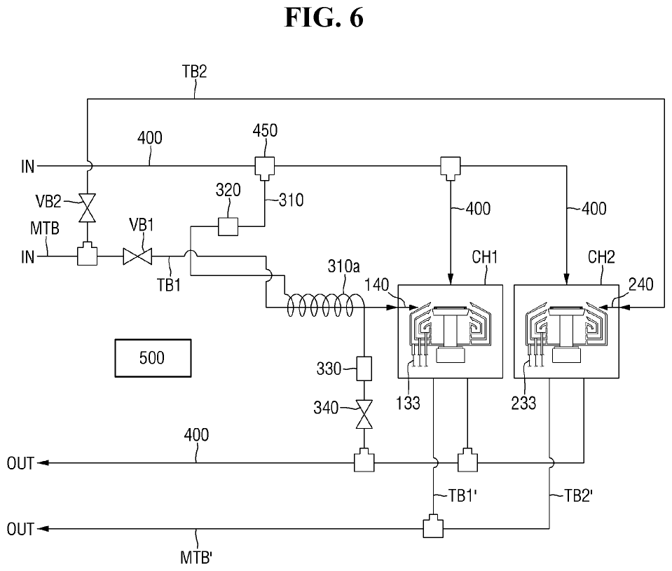

In some embodiments, the first processing solution may be introduced by a first inflow line 140 and recovered by the first recovery lines 133. The first inflow line 140 may be connected to the first pipe TB1 of FIG. 3. The first recovery lines 133 may be connected to a first outflow pipe TB1′ (see FIG. 6). The second processing solution may be introduced by a second inflow line 240 and recovered by the second recovery lines 233. The second inflow line 240 may be connected to the second pipe TB2 of FIG. 3. The second recovery lines 233 may be connected to a second outflow pipe TB2′ (see FIG. 6).

FIG. 5 is an exemplary diagram explaining the first valve box of FIG. 3.

Referring to FIG. 5, a temperature adjusting pipe 310 and at least a part of the first pipe TB1 may be disposed in the first valve box VBX1.

The temperature adjusting pipe 310 may surround at least a part of the first pipe TB1. For example, the temperature adjusting pipe 310 may include a first portion 310a and second portion(s) 320b. The first portion 310a of the temperature adjusting pipe 310 may surround at least a part of the first pipe TB1. The first portion 310a of the temperature adjusting pipe 310 may form a heat exchanger with the part of the first pipe TB1 that it surrounds. The second portion(s) 310b of the temperature adjusting pipe 310 may be the remaining portion except the first portion 310a.

In some embodiments, the temperature adjusting pipe 310 may adjust the temperature of the first processing solution. Specifically, a temperature adjusting solution may be transferred within the temperature adjusting pipe 310. The temperature of the first processing solution may be adjusted using the temperature adjusting solution. For instance, the first processing solution may flow through the first pipe TB1. The temperature adjusting solution may flow through the temperature adjusting pipe 310. The temperature of the temperature adjusting solution may be lower than the temperature of the first processing solution. Since the first portion 310a of the temperature adjusting pipe 310 surrounds the first pipe TB1, the temperature of the first processing solution flowing through the first pipe TB1 can be adjusted.

Since the length of the second pipe TB2 is longer than the length of the first pipe TB1, the temperature of the second processing solution provided to the second chamber CH2 by the second pipe TB2 may differ from the temperature of the first processing solution provided to the first chamber CH1 by the first pipe TB1. When using the substrate processing apparatus according to some embodiments, the temperature of the first processing solution may be controlled using the temperature adjusting pipe 310. Accordingly, the temperature of the second processing solution provided to the second chamber CH2 may be substantially identical to that of the first processing solution provided to the first chamber CH1. That is, the processing solution at the inputs to the first and second chambers CH1 and CH2 may be made substantially identical and thus may have substantially identical temperatures within the first and second chambers CH1 and CH2 during the processing performed by the first and second chambers CH1 and CH2. As such, processing conditions may be made substantially identical and the resulting products being formed in the first and second chambers CH1 and CH2 may be made with less deviation between them. For example, a pattern formed in the first chamber CH1 may be substantially identical to that of the pattern formed in the second chamber CH2.

The first valve box VBX1 of the substrate processing apparatus according to some embodiments may further include a temperature sensor 320, a flow rate measuring device 330 (a flow meter or a flow sensor), and a flow control valve 340.

The temperature sensor 320, the flow rate measuring device 330, and the flow control valve 340 (e.g., a valve having a variable aperture) may be inserted into or otherwise connected to the temperature adjusting pipe 310. The temperature sensor 320 may measure the temperature of the temperature adjusting solution flowing to the temperature adjusting pipe 310. The temperature of the first processing solution may be adjusted by adjusting the temperature of the temperature adjusting solution. The flow rate measuring device 330 may measure the flow rate of the temperature adjusting solution flowing to the temperature adjusting pipe 310. The temperature of the first processing solution may be adjusted by adjusting the flow rate of the temperature adjusting solution. The flow control valve 340 may control the flow rate of the temperature adjusting solution flowing to the temperature adjusting pipe 310 and be adjusted in response to the measurement of the flow rate by the flow rate measuring device 330.

Controller 500 (such as a micro-controller, a processor (CPU, GPU, DSP, etc.), an FPGA, a computer, etc.) may control the flow rate of the temperature adjusting solution by controlling the flow control valve 340 to increase or decrease flow resistance of the temperature adjusting solution within the temperature adjusting pipe 310 (e.g., increase or decrease the size of the aperture of the flow control valve 340). The controller 500 may be operatively connected (e.g., with wires) to the temperature sensor 320 and the flow rate measuring device 330 to respectively receive temperature data and flow rate data. The controller 500 may be operatively connected to the flow control valve 340 to adjust the flow rate of the temperature adjusting solution.

FIG. 6 is a conceptual diagram explaining a substrate processing apparatus according to some embodiments of the present disclosure. A method for adjusting the temperature of the first processing solution using the temperature adjusting solution will be described in more detail with reference to FIG. 6.

Referring to FIG. 6, the substrate processing apparatus in accordance with some embodiments may further include a cooling flow path 400, a cooling fluid diverter 450, and a first pipe valve VB1 and a second pipe valve VB2.

The cooling flow path 400 may be connected to the first chamber CH1 and the second chamber CH2. The cooling flow path 400 may circulate a cooling fluid (e.g., water) to cool portions of the first chamber CH1 and the second chamber CH2. For example, cooling fluid may be provided to the first and second chamber CH1 and CH2 to cool the first support unit 110 of FIG. 4 in the first chamber CH1 to cool the second support unit 210 of FIG. 4 in the second chamber CH2. The temperature adjusting solution may be provided to the temperature adjusting pipe 310 by diverter 450 and comprise a portion of the cooling fluid. The temperature adjusting solution is supplied to the first chamber CH1 by the temperature adjusting pipe 310. The diverter 450 may be a tee (a divider/combiner type of pipe fitting) and may also include a valve. Each of the chambers CH1 and CH2 may have an internal cooling flow path (e.g., pipes, tubes, etc.) the receives the cooling fluid and provides the same within or adjacent to the corresponding support unit (110 or 210) to absorb heat from the same (e.g., flowing the cooling fluid through a heat exchanger provided with the corresponding support unit).

The diverter 450 may be provided between the cooling flow path 400 and the temperature adjusting pipe 310. The diverter 450 may divert a portion of the cooling fluid flowing through the cooling flow path 400 to be diverted to the temperature adjusting pipe 310. The diverter 450 may comprise a cooling valve what when opened, the temperature adjusting solution flows to the temperature adjusting pipe 310. When the cooling valve of the diverter 450 is closed, the temperature adjusting solution does not flow to the temperature adjusting pipe 310.

The first pipe valve VB1 may be connected to/inserted within the first pipe TB1. The first pipe valve VB1 may adjust the flow rate of the first processing solution flowing through the first pipe TB1. The first processing solution may be supplied to the first chamber CH1 (e.g., to the first nozzle structure 120 via the first inflow line 140) through the first pipe TB1. At least a part of the first pipe TB1 may be surrounded by the first portion 310a of the temperature adjusting pipe 310. For example, the first portion 310a of the temperature adjusting pipe 310 may be disposed in a spiral shape (e.g., a helical shape) to surround at least a part of the first pipe TB1. As the first portion 310a of the temperature adjusting pipe 310 is arranged in a spiral shape, heat may be efficiently exchanged between the temperature adjusting solution and the first processing solution so that the temperature of the first processing solution flowing through the first pipe TB1 can be adjusted.

The second pipe valve VB2 may be connected to/inserted within the second pipe TB2 and may adjust the flow rate of the second processing solution flowing through the second pipe TB2 that is supplied to the second chamber CH2 by the second pipe TB2 (e.g., to the second nozzle structure 220 via the first inflow line 240). FIG. 6 illustrates that the second pipe TB2 is not provided with a temperature adjusting pipe and related structure as shown and described with respect to the first pipe TB1. However, in alternative embodiments, such temperature adjusting pipe and related structure may also be provided to adjust the temperature of the processing solution flowing through the second pipe TB2.

FIG. 6 illustrates the cooling flow path 400 includes a portion exiting both of the first and second chamber CH1 and CH2. The cooling fluid may be combined into a single pipe and output from the substrate processing apparatus. In addition, the temperature adjusting solution of the temperature adjusting pipe 310 (comprising a portion of the cooling fluid of the cooling flow path 400) may also be rejoined into the cooling flow path 400. In addition, the first processing solution and second processing solution recovered from the first and second chambers CH1 and CH2 are output from the first and second chambers by first and second output pipes TB1′ and TB2′, respectively, and combined by a tee pipe to be output from the substrate processing apparatus by main output pipe MTB′. The dividers and combiners described herein may be and/or include tee pipe fittings (and may optionally include a valve) and are represented in FIG. 6 by a block “T” symbol.

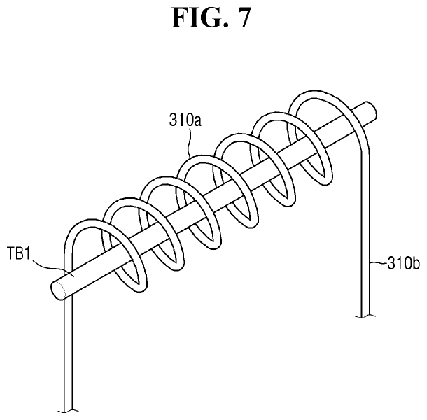

FIG. 7 is an enlarged view illustrating the first pipe and an exemplary first portion of the temperature adjusting pipe of FIG. 6.

Referring to FIG. 7, the first pipe TB1 may extend in one direction. The first portion 310a of the temperature adjusting pipe 310 may have a spiral shape. The first portion 310a of the temperature adjusting pipe 310 may surround and contact at least a part of the first pipe TB1. In some embodiments, the length of the first portion 310a of the temperature adjusting pipe 310 may be 450 mm or more and 550 mm or less, but the present invention is not limited thereto (“length” here referring to the path length of the first portion 310a (the distance along the axis of the pipe 310 of first portion 310a)—as opposed the dimension of the volume which is occupied by the first portion 310a). The first portion 310a of the temperature adjusting pipe 310 may be a spiral tube that is wrapped around the first pipe TB1 (e.g., in a helical shape to contact the outer surface of the first pipe TB1). The first portion 310a of the temperature adjusting pipe 310 may contact the outer surface of the first pipe TB1. Alternatively (or in addition) a heat conductive material (not shown) may connect (e.g., contact both, and/or be formed around and between) the first portion 310a of the temperature adjusting pipe 310 and the first pipe TB1.

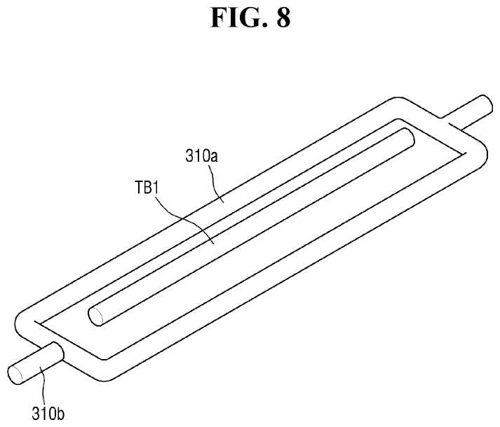

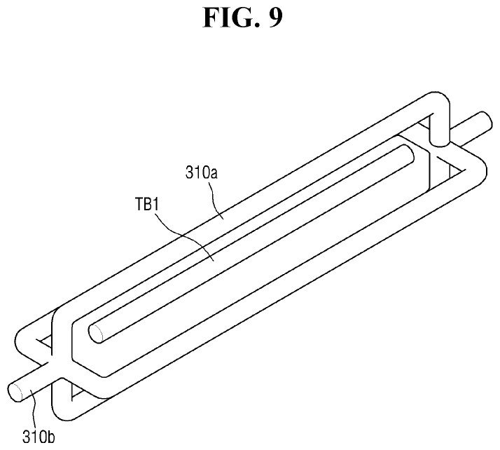

FIGS. 8 and 9 are views explaining the substrate processing apparatus according to some embodiments. For convenience of description, the descriptions different from those described with reference to FIGS. 1 to 7 will be mainly described.

First, referring to FIG. 8, the first portion 310a of the temperature adjusting pipe 310 may not have a spiral shape. The first portion 310a of the temperature adjusting pipe 310 does not surround the first pipe TB1. The first portion 310a of the temperature adjusting pipe 310 may extend in parallel with the first pipe TB1. The first portion 310a of the temperature adjusting pipe 310 may extend in parallel with the first pipe TB1 in one side and the other side of the first pipe TB1. Since the first portion 310a of the temperature adjusting pipe 310 is disposed adjacent to the first pipe TB1, the temperature of the first processing solution flowing to the first pipe TB1 may be adjusted by the temperature adjusting solution flowing to the first portion 310a of the temperature adjusting pipe 310. A heat conductive material (not shown) may connect (e.g., contact both, and/or be formed around and between) the first portion 310a of the temperature adjusting pipe 310 and the first pipe TB1.

Referring to FIG. 9, the first portion 310a of the temperature adjusting pipe 310 may not have a spiral shape. The first portion 310a of the temperature adjusting pipe 310 may extend in parallel with the first pipe TB1. The first part 310a of the temperature adjusting pipe 310 may extend in parallel with the first pipe TB1 in an upper part, a lower part, one side and the other side of the first pipe TB1. The first portion 310a of the temperature adjusting pipe 310 may be disposed adjacent to the first pipe TB1. Since the first portion 310a of the temperature adjusting pipe 310 is disposed adjacent to the first pipe TB1, the temperature of the first processing solution flowing to the first pipe TB1 may be adjusted by the temperature adjusting solution flowing to the first part 310a of the temperature adjusting pipe 310. A heat conductive material (not shown) may connect (e.g., contact both, and/or be formed around and between) the first portion 310a of the temperature adjusting pipe 310 and the first pipe TB1

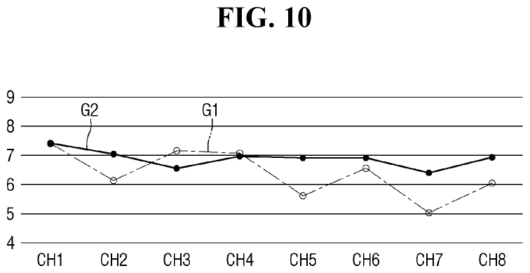

FIG. 10 is a graph illustrating the effect of the substrate processing apparatus according to some embodiments.

Referring to FIG. 10, a first graph G1 is a graph illustrating pattern element spacing of a pattern (e.g., the distance between facing sides of adjacent pattern elements) formed in the first to eighth chambers CH1 to CH8 when the temperature adjusting pipe 310 is not disposed. A second graph G2 is a graph illustrating pattern element spacing of a pattern formed in the first to eighth chambers CH1 to CH8 when the temperature adjusting pipe 310 is disposed.

The average value of the pattern element spacing of the pattern measured through the first graph G1 is about 6.36, while the standard deviation thereof is 0.76. The average value of the pattern element spacing of the pattern measured through the second graph G2 is about 6.88, while the standard deviation thereof is 0.29.

This confirms that the standard deviation when the temperature adjusting pipe 310 is disposed is smaller than that when the temperature adjusting pipe 310 is not disposed. Since the standard deviation of the pattern element spacing of the pattern formed in the first to eighth chambers CH1 to CH8 is small, the pattern element spacing of the pattern may be determined to be formed more uniformly. In other words, when using the substrate processing apparatus according to some embodiments, a uniform pattern element spacing of the pattern can be formed.

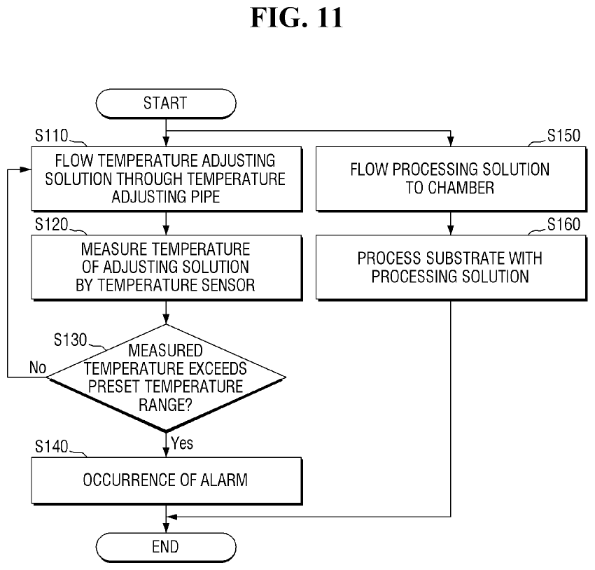

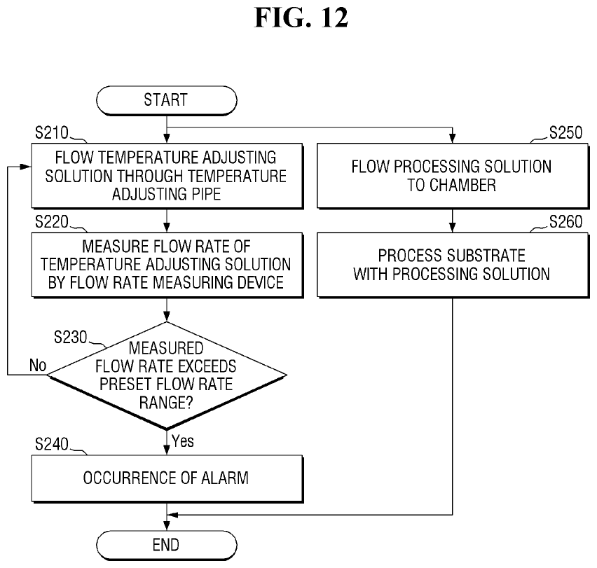

FIGS. 11 and 12 are flowcharts explaining methods of manufacturing a semiconductor device according to some embodiments. The methods may be implemented with any of the substrate processing apparatus embodiments described herein and repetitive detailed description of the same need not be repeated here.

Referring to FIGS. 6 and 11, the method for manufacturing a semiconductor device according to some embodiments may include allowing the temperature adjusting solution to flow within the temperature adjusting pipe 310 (S110), measuring the temperature of the temperature adjusting solution by the temperature sensor 320 (S120), and determining whether or not the measured temperature of the temperature adjusting solution exceeds a preset temperature range (S130). In addition, when the measured temperature of the temperature adjusting solution is determined to be at the high end of the preset temperature range (e.g., the temperature adjusting solution exceeds a first predetermined temperature in the preset temperature range) (S130), the flow rate of the temperature adjustable solution may be increased, such as by operating the valve of diverter 450 and/or the flow control valve 340 to increase their aperture and provide less restriction to the flow of the temperature adjusting solution in the temperature adjusting pipe 310. When the measured temperature of the temperature adjusting solution is determined to be at the low end of the preset temperature range (e.g., the temperature adjusting solution falls below a second predetermined temperature, lower than the first predetermined temperature, in the preset temperature range) (S130), the flow rate of the temperature adjustable solution may be decreased, such as by operating the valve of diverter 450 and/or the flow control valve 340 to decrease their aperture and provide more restriction to the flow of the temperature adjusting solution in the temperature adjusting pipe 310. Thus, the controller may operate an adjustable valve in the temperature adjusting solution flow path to increase or decrease the flow rate of the temperature adjusting solution to maintain a desired heat transfer between the temperature adjusting solution and the first processing solution, thereby adjusting the temperature of the first processing solution (e.g., at its introduction to the first chamber CH1) to be substantially the same as the temperature of the second processing solution (e.g., at its introduction to the second chamber CH2). When the temperature adjusting solution is the cooling fluid diverted from the cooling flow path 400, the temperature adjusting solution may have a temperature lower than that of the temperature processing solution, and thus lower the temperature of processing solution being provided to the chamber that is closer to the main tube MTB and/or has a shorter flow path to its corresponding chamber from the main tube MTB (e.g., CH1 and/or CH3) as compared to that of other chambers of the corresponding tower and/or other chambers of the substrate processing apparatus (e.g., CH2 and/or CH4).

As steps S110, S120 and S130 are repetitively performed, steps S150 and S160 may also be performed at the same time. As shown in FIG. 11, the processing solution flows to a corresponding chamber (e.g., CH1) (S150). The processing solution has its temperature adjusted by virtue of the flow of the temperature adjusting solution in the temperature adjusting pipe (S110) as described herein and is provided to the chamber to process a substrate (S160) to form semiconductor devices with the substrate. For example, a cleaning process, a deposition process, and/or an etching process may be performed on the substrate in the chamber using the processing solution.

When the measured temperature of the temperature adjusting solution exceeds the preset temperature range, an alarm may occur (S140). The alarm may trigger the controller to change the temperature of the cooling fluid in the cooling flow path 400 to be within the preset temperature range and/or temporarily suspend operations S150 and S160. In addition, when the measured temperature of the temperature adjusting solution does not exceed the preset temperature range, the temperature adjusting solution may continue to flow through the temperature adjusting pipe 310. As described above, the substrate processing apparatus according to some embodiments may have an interlock function. Accordingly, the temperature of the first processing solution may be more efficiently adjusted.

Referring to FIGS. 6 and 12, the method for manufacturing a semiconductor device according to some embodiments may include allowing the temperature adjusting solution to flow to the temperature adjusting pipe 310 (S210), measuring the flow rate of the temperature adjusting solution by the flow rate measuring device 330 (S220), and determining whether or not the measured flow rate of the temperature adjusting solution exceeds a preset flow rate range (S230).

When the measured flow rate of the temperature adjusting solution exceeds the preset flow rate range, the alarm may occur (S240). The alarm may trigger the flow rate of the temperature adjusting solution to be controlled (increased or decreased by the controller to fall within the preset temperature range) using the temperature adjusting valve 340. When the measured flow rate of the temperature adjusting solution does not exceed the preset flow rate range, the temperature adjusting solution may continue flowing to the temperature adjusting pipe 310 with the flow rate conditions unaltered.

As steps S210, S220 and S230 are repetitively performed, steps S250 and S260 may also be performed at the same time. As shown in FIG. 11, the processing solution flows to a corresponding chamber (e.g., CH1) (S250). The processing solution has its temperature adjusted by virtue of the flow of the temperature adjusting solution in the temperature adjusting pipe (S210) as described herein and is provided to the chamber to process a substrate (S260) to form semiconductor devices with the substrate. For example, a cleaning process, a deposition process, and/or an etching process may be performed on the substrate in the chamber using the processing solution. It will be appreciated that the methods of FIGS. 11 and 12 may be performed together, and that steps S110, S150 and S160 are the same as steps S210, S250 and S260, respectively.

As described above, the substrate processing apparatus according to some embodiments may have an interlock function. Accordingly, the temperature of the first processing solution may be more efficiently adjusted.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device manufacturing method, comprising:
loading a first substrate and a second substrate into a substrate processing apparatus, wherein the first substrate is loaded into a first chamber and the second substrate is loaded into a second chamber on the first chamber; and
processing the loaded first substrate in the first chamber and the loaded second substrate in the second chamber,
wherein the substrate processing apparatus comprises:
the first and second chambers;
a first pipe through which flows a first processing solution to the first chamber to process the first substrate;
a second pipe through which flows a second processing solution to the second chamber to process the second substrate; and
a temperature adjusting pipe configured to surround at least a part of the first pipe, through which flows a temperature adjusting solution to adjust a temperature of the first processing solution,
wherein a length of the first pipe is shorter than a length of the second pipe.

2. The semiconductor device manufacturing method of claim 1, wherein a temperature of the temperature adjusting solution is lower than the temperature of the first processing solution.

3. The semiconductor device manufacturing method of claim 1, wherein the substrate processing apparatus further comprises:
a first support unit disposed in the first chamber and configured to support the first substrate and rotate the first substrate;
a second support unit disposed in the second chamber and configured to support the second substrate and rotate the second substrate; and
a cooling flow path configured to supply a cooling fluid to cool the first and second support units,
wherein the temperature adjusting pipe is connected to the cooling flow path.

4. The semiconductor device manufacturing method of claim 3, wherein the temperature adjusting solution is a portion of the cooling fluid diverted from the cooling flow path.

5. The semiconductor device manufacturing method of claim 1, wherein the substrate processing apparatus further comprises:
a flow meter connected to the temperature adjusting pipe and configured to measure a flow rate of the temperature adjusting solution.

6. The semiconductor device manufacturing method of claim 5, wherein the temperature of the first processing solution is adjusted by controlling the flow rate of the temperature adjusting solution.

7. A substrate processing apparatus, comprising:
a first chamber configured to process a first substrate;
a second chamber disposed on the first chamber, the second chamber being configured to process a second substrate;
a first pipe configured to supply a first processing solution to the first chamber to process the first substrate;
a second pipe configured to supply a second processing solution supplied to the second chamber to process the second substrate; and
a temperature adjusting pipe surrounding at least a part of the first pipe and configured to flow a temperature adjusting solution to adjust a temperature of the first processing solution,
wherein a length of the first pipe is smaller than a length of the second pipe.

8. The substrate processing apparatus of claim 7, wherein a temperature of the temperature adjusting solution is lower than the temperature of the first processing solution.

9. The substrate processing apparatus of claim 7, further comprising a temperature sensor connected to the temperature adjusting pipe and configured to measure the temperature of the temperature adjusting solution.

10. The substrate processing apparatus of claim 7, further comprising a flow meter connected to the temperature adjusting pipe and configured to measure a flow rate of the temperature adjusting solution.

11. The substrate processing apparatus of claim 10, further comprising:
a flow control valve provided with the temperature adjusting pipe; and
a controller configured to control the control valve to adjust the flow rate of the temperature adjusting solution to adjust the temperature of the first processing solution.

12. The substrate processing apparatus of claim 7, further comprising:
a first support unit disposed in the first chamber and configured to support the first substrate and rotate the first substrate;
a second support unit disposed in the second chamber and configured to support the second substrate and rotate the second substrate; and
a cooling flow path configured to supply a cooling fluid to cool the first and second support units,
wherein the temperature adjusting pipe is connected to the cooling flow path.

13. The substrate processing apparatus of claim 12, wherein the temperature adjusting solution is a portion of the cooling fluid diverted from the cooling flow path.

14. The substrate processing apparatus of claim 7, wherein the temperature adjusting pipe includes a first portion surrounding the first pipe having a length in the range of 450 mm to 550 mm.

15. The substrate processing apparatus of claim 14, wherein the first portion is disposed in a helical shape that wraps around at least a part of the first pipe.

16. A substrate processing apparatus, comprising:
a first chamber configured to process a first substrate, wherein the first chamber includes a first support unit configured to support the first substrate and rotate the first substrate;
a second chamber disposed on the first chamber, the second chamber configured to process a second substrate, wherein the second chamber includes a second support unit configured to support the second substrate and rotate the second substrate;
a valve box disposed under the first chamber;
a first pipe extending from the valve box to the first chamber to supply a first processing solution to the first chamber to process the first substrate, wherein at least a part of the first pipe is disposed in the valve box;
a second pipe through extending to the second chamber to supply a second processing solution to the second chamber to process the second substrate;
a cooling flow path configured to supply a cooling fluid to cool the first and second support units; and
a temperature adjusting pipe connected to the cooling flow path and having a first portion surrounding at least a part of the first pipe, the temperature adjusting pipe configured to flow a temperature adjusting solution to adjust the temperature of the first processing solution in the first pipe,
the first portion of the temperature adjusting pipe is wrapped around at least a part of the first pipe, and
a length of the first pipe is shorter than a length of the second pipe.

17. The substrate processing apparatus of claim 16, further comprising a flow meter connected to the temperature adjusting pipe to measure the flow rate of the temperature adjusting solution.

18. The substrate processing apparatus of claim 17, further comprising:
a flow control valve provided with the temperature adjusting pipe; and
a controller configured to control the flow control valve to adjust the flow rate of the temperature adjusting solution to adjust the temperature of the first processing solution.

19. The substrate processing apparatus of claim 16, wherein a length of the first portion is in the range of 450 mm to 550 mm.

20. The substrate processing apparatus of claim 17, wherein the temperature adjusting solution is a portion of the cooling fluid diverted from the cooling flow path.
